(19) United States
(12) Patent Application Publication
(10) Pub. No.: US 2019/0244791 A1
(43) Pub. Date: Aug. 8, 2019

(54) RAISING-AND-LOWERING MECHANISM, STAGE AND PLASMA PROCESSING APPARATUS

(71) Applicant: Tokyo Electron Limited, Tokyo (JP)

(72) Inventor: Jun Young CHUNG, Gyeonggi-do (KR)

(21) Appl. No.: 16/263,114

(22) Filed: Jan. 31, 2019

(30) Foreign Application Priority Data
Feb. 5, 2018 (JP) 2018-018005

(51) Int. Cl. H01J 37/32; H01L 21/02; H01L 21/311; H01L 21/683

(52) U.S. Cl. CPC H01J 37/32449; H01J 37/32917; H01J 2237/3347; H01L 21/31116; H01L 21/6833; H01L 21/02274

(57) ABSTRACT

A raising-and-lowering mechanism for a processing target is provided. The raising-and-lowering mechanism includes: a pin insertion hole that is provided in a stage in an up-and-down direction, the processing target that is to be processed in a processing chamber being placed on the stage; a lifter pin that is raised and lowered in the up-and-down direction; a lubrication unit that is provided at a predetermined height between the pin insertion hole and the lifter pin and supplies a lubricant to the lifter pin; a drive unit that drives the lifter pin in the up-and-down direction; and a heat-transfer gas supplying unit that includes a heat-transfer gas supplying path that penetrates through to the pin insertion hole at a position higher than the lubrication unit and supplies a heat-transfer gas to the pin insertion hole.

### BACKGROUND OF THE INVENTION

### 1. Field of the Invention

The present invention relates to a raising-and-lowering mechanism, a stage and a plasma processing apparatus.

### 2. Description of the Related Art

In recent years, semiconductor manufacturing apparatuses are increasingly required to perform etching of holes, or the like, with a high aspect ratio when generating holes such as a contact hole, and grooves (refer to Patent Document 1, for example). In order to etch holes with a high aspect ratio with high speed, RF high-frequency power, which is supplied to a stage on which a substrate is placed, is increasing gradually than before.

### CITATION LIST

### Patent Document

### [Patent Document 1] Japanese Unexamined Patent Application Publication No. 2014-17438

### SUMMARY OF THE INVENTION

### Technical Problem

However, when the RF high-frequency power increases, because a heat-transfer gas is supplied between an upper surface of the stage and a lower surface of the substrate, the probability increases that an abnormal discharge occurs in a heat-transfer gas hole that penetrates through to the upper surface of the stage.

In view of the above-described problem, an object of an aspect of the present invention is to prevent an abnormal discharge at the stage.

### Solution to Problem

In order to solve the above-described problem, according to an aspect of the present invention, a raising-and-lowering mechanism is provided. The raising-and-lowering mechanism includes: a pin insertion hole that is provided in a stage in an up-and-down direction, the stage being used for placing an object to be processed (a processing target) that is to be processed in a processing chamber; a lifter pin that is raised and lowered in the up-and-down direction; a lubrication unit that is provided at a predetermined height between the pin insertion hole and the lifter pin and supply a lubricant to the lifter pin; a drive unit that drives the lifter pin in the up-and-down direction; and a heat-transfer gas supplying unit that includes a heat-transfer gas supplying path that communicates with the pin insertion hole at a position higher than the lubrication unit and supplies a heat-transfer gas to the pin insertion hole.

### Advantageous Effects of Invention

According to an aspect of the present invention, it is possible to prevent an abnormal discharge at the stage.

### BRIEF DESCRIPTION OF THE DRAWINGS

FIG. 1 is a drawing illustrating an example of a plasma processing apparatus according to an embodiment of the present invention.

FIG. 2 is a drawing illustrating an example of a conventional stage.

FIG. 3 is a drawing illustrating an example of a stage (when a lifter pin is lowered) according to an embodiment of the present invention.

FIG. 4 is a drawing illustrating an example of a stage (when a lifter pin is raised) according to an embodiment of the present invention.

FIG. 5 is a drawing illustrating a modified example of a stage according to an embodiment of the present invention.

### DETAILED DESCRIPTION OF THE PREFERRED EMBODIMENTS

In the following, one or more embodiments of the present invention will be described while making reference to the drawings. It should be noted that, in the present specification and the drawings, a same reference numeral is given to substantially a same structure, and duplicated descriptions will be omitted.

[Plasma Processing Apparatus]

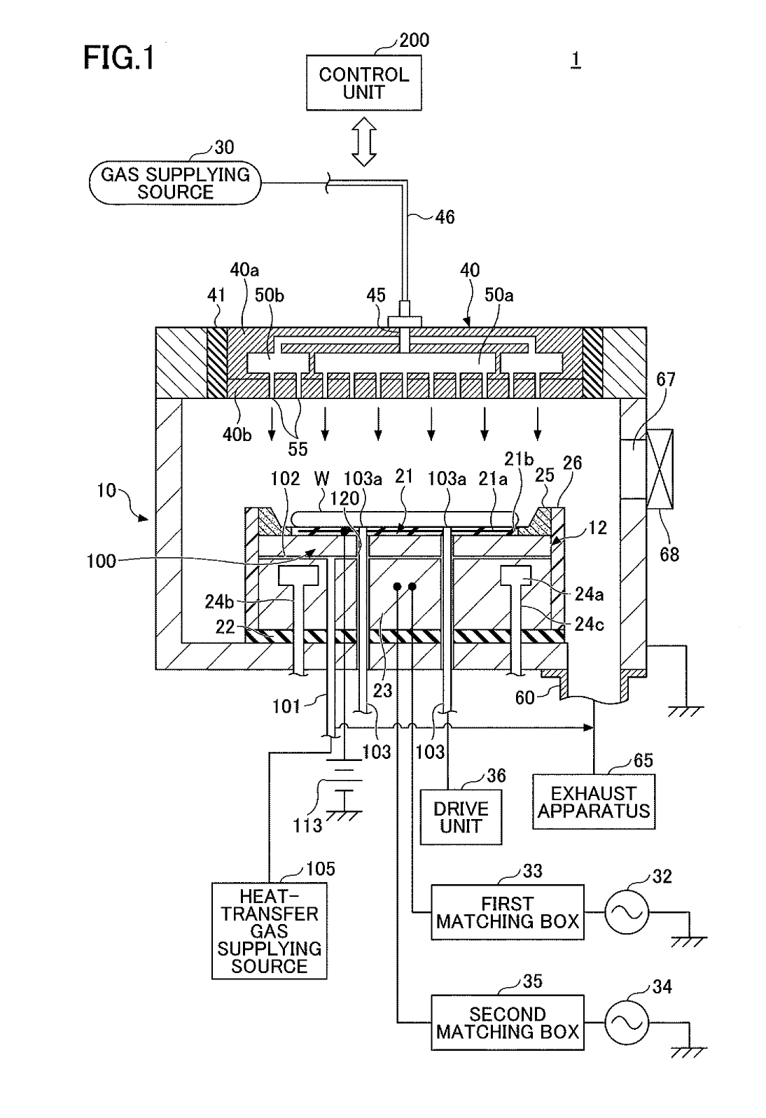

First, referring to FIG. 1, an example of an overall structure of a plasma processing apparatus 1 according to an embodiment of the present invention will be described. FIG. 1 is a drawing illustrating an example of a plasma processing apparatus 1 according to an embodiment of the present invention. The plasma processing apparatus 1 is an example of a semiconductor manufacturing apparatus that is enabled to etch a semiconductor wafer W as an object to be processed (hereinafter, referred to as a wafer W) to generate a hole or a groove with high aspect ratio by using plasma.

The plasma processing apparatus 1 includes a cylindrical processing chamber 10 made of aluminum, to the surface of which Alumite treatment (anodizing treatment) is applied. The processing chamber 10 is grounded. A stage 12 is provided in the processing chamber 10. The wafer W is placed on the stage 12. Plasma processing, such as etching processing, is applied to the wafer W in the processing chamber 10. The stage 12 is disposed in the bottom of the processing chamber 10 via an insulative support unit 22.

The stage 12 includes, for example, an electro-static chuck 21 made of aluminum and a base 23. The electro-static chuck 21 is provided on an upper surface of the base 23. The electro-static chuck 21 includes a chuck electrode 21a made of a conductive film, the chuck electrode 21a being sandwiched between insulating layers 21b. A direct current (DC) power supply 113 is connected to the chuck electrode 21a. The electro-chuck 21 attracts the wafer W via Coulomb force according to a voltage from the DC power supply 113 and holds the wafer W on the electro-static chuck 21. A focus ring 25 is arranged in the circumference of the wafer W, circularly surrounding the wafer W on a circumference upper surface of the stage 12, the focus ring 25 being made of silicon or quartz. The circumferences of the focus ring 25 and the stage 12 are covered by a cylindrical insulator ring 26.

A first high-frequency power supply 32 is connected to the base 23 of the stage 12 via a first matching box 33. Further, a second high-frequency power supply 34 is connected to the base 23 via a second matching box 35. For example, the first high-frequency power supply 32 applies, to the stage 12, 3 kW high-frequency power with a first frequency (e.g., 40 MHz) that is appropriate for generating plasma in the processing chamber 10. The second high-frequency power supply 34 applies, to the stage 12, equal-to-or-greater-than-5 kW high-frequency power with a frequency (e.g., 3 MHz) that is lower than the first frequency and is appropriate for drawing an ion in the plasma to the wafer W on the stage 12. In this way, the stage 12 is not only used for placing a wafer W thereon, but also used for functioning as a lower electrode.

A refrigerant tube 24a is provided within the stage 12. A refrigerant with predetermined temperature is supplied to the refrigerant tube 24a from a chiller unit via tubes 24b and 24c to be circulated. With the above arrangement, temperature of the wafer W on the electro-static chuck 21 may be adjusted to a predetermined temperature.

An exhaust pipe 60, which forms an exhaust port, is provided in the bottom of the processing chamber 10, and the exhaust pipe 60 is connected to an exhaust apparatus 65. The exhaust apparatus 65 includes a vacuum pump such as a turbo-molecular pump, a dry pump, or the like. The exhaust apparatus 65 reduces pressure of the processing space in the processing chamber 10 to a predetermined degree of vacuum and exhausts the gas in the processing chamber 10.

A gate valve 68 is attached to a side wall of the processing chamber 10. A transport port 67 is opened and closed by the gate valve 68 when loading and unloading the wafer W.

A gas shower head 40 is provided on the ceiling of the processing chamber 10 via a ring-shaped insulating body 41 so as to close the ceiling. With the above arrangement, the gas shower head 40 has a function as an upper electrode with a ground potential, and high-frequency power from the first high-frequency power supply 32 used for generating plasma is capacitively applied to between the stage 12 and the gas shower head 40.

The gas shower head 40 includes an electrode support body 40a and an electrode plate 40b. The electrode plate 40b includes many gas ventilation holes 55. The electrode supports body 40a supports the electrode plate 40b in such a way that the electrode plate 40b is enabled to be attached and detached. Within the electrode support body 40a, a buffer room 50a is provided in the center and a buffer room 50b is provided surrounding the circumference of the buffer room 50a. A gas supplying source 30 is connected to a gas inlet 45 via a gas supplying pipe 46. With the above arrangement, a predetermined gas that is supplied from the gas supplying source 30 goes through the buffer rooms 50a and 50b via the gas supplying pipe 46, and is diffused in the buffer rooms 50a and 50b to be supplied into the processing chamber 10.

Multiple (e.g., three) lifter pins 103 are provided within the stage 12. The lifter pins 103 are used for raising and lowering the wafer W in order to pass and receive the wafer W to and from loading arms. Pin insertion holes that penetrate through the stage 12 are provided within the stage 12, and the lifter pins 103 are inserted in the pin insertion holes.

Each of the lifter pins 103 is connected to a drive unit 36. The drive unit 36 includes a motor, or the like, and raises and lowers the lifter pins 103. In other words, the lifter pins 103 penetrate through the bottom of the processing chamber 10 and the support unit 22, are inserted through the pin insertion holes 120 provided within the stage 12, and are raised and lowered in the up-and-down direction according to driving of the drive unit 36.

When the lifter pins 103 are raised, the wafer W that has been received from the loading arms is supported by tips 103a of the lifter pins 103. Afterwards, when the lifter pins 103 are lowered and retracted into the pin insertion holes 120, the wafer W is placed on the stage 12.

When the lifter pins 103 are raised again after the wafer W is processed, the tips 103a of the lifter pins 103 touch the lower surface of the wafer W, and the wafer W is raised. The raised wafer W is passed to the loading arms and is carried out of the processing chamber 10.

The stage 12 includes a heat-transfer gas supplying unit 100 that supplies a heat-transfer gas such as a He gas, Ar gas, etc., to between the lower surface of the wafer W and the upper surface of the electro-static chuck 21. The heat-transfer gas supplying unit 100 includes a heat-transfer gas supplying path 102 and a heat-transfer gas supplying pipe 101 that are used for supplying a heat-transfer gas in a horizontal direction within the base 23. A heat-transfer gas output from the heat-transfer gas supplying source 105 flows in the heat-transfer gas supplying pipe 101, goes through the heat-transfer gas supplying path 102 that communicates with the heat-transfer gas supplying pipe 101, goes through the pin insertion holes 120 included in the stage 12, and is supplied onto the upper surface of the electro-static chuck 21.

The control unit 200 includes a CPU (Central Processing Unit), a ROM (Read Only Memory), and a RAM (Random Access Memory) (not shown). The CPU performs plasma processing according to various recipes stored in memory areas of the ROM and RAM. In the recipes, processing time, internal processing chamber temperatures (upper electrode temperature, side wall temperature of the processing chamber, ESC temperature, etc.), pressure (gas exhaust), high-frequency power, voltage, various gas flow rates, heat-transfer gas flow rates, etc., are described.

With the above arrangement, the control unit 200 controls each of units attached to the plasma processing apparatus 1 such as the gas supplying source 30, the exhaust apparatus 65, the DC power supply 113, the first high-frequency power supply 32, the matching box 33, the second high-frequency power supply 34, the matching box 35, the heat-transfer gas supplying source 105, the drive unit 36, etc.

In the plasma processing apparatus 1 as described above, in order to perform predefined processing such as etching, first, the gate valve 68 is opened, and the wafer W held on the loading arms enters the processing chamber 10 from the loading port 67.

Next, the wafer W is moved from the loading arms to the lifter pins 103 that protrude from the upper surface of the electro-static chuck 21, and held on the tips 103a of the lifter pins 103. Next, the loading arms are retracted out of the processing chamber 10 through the loading port 67, the lifter pins 103 are lowered and stored within the electro-static chuck 21, and the wafer W is placed on the electro-static chuck 21.

After the loading of the wafer W, the gate valve 68 is closed, a desired gas such as an etching gas is supplied from the gas supplying source 30, the predetermined gas is introduced into the processing chamber 10 with a predetermined flow rate, and the pressure in the processing chamber 10 is reduced to a set value according to the exhaust by the exhaust apparatus 65.

Furthermore, predetermined high-frequency power is applied to the stage 12 from the first high-frequency power supply 32. Further, a DC current is applied to the chuck electrode 21a of the electro-static chuck 21 from the DC power supply 113, and the wafer W is attracted to and held onto the electro-static chuck 21. The gas that has been introduced through the gas shower head 40 is plasmatized by the high-frequency power. The wafer W is etched by the generated plasma.

After completion of the plasma etching, the supplying of the heat-transfer gas is stopped when detaching the wafer W from the electro-static chuck 21. Further, while maintaining the pressure in the processing chamber 10 at a predetermined pressure by introducing an inert gas into the processing chamber 10, after applying, to the chuck electrode 21a, a voltage whose electrical polarity is opposite to the voltage that has been applied to the chuck electrode 21a during the plasma processing, applying the voltage is stopped. With the above-described operations, static elimination processing is performed in which the static electricity of charges included in the electro-static chuck 21 and the wafer W is removed. In a state as described above, the lifter pins 103 are raised, the wafer W is lifted from the electro-static chuck 21, and the wafer W is detached from the electro-static chuck 21. The gate valve 68 is opened, the loading arms go into the processing chamber 10, the lifter pins 103 are lowered, and the wafer W is held on the loading arms. Next, the loading arms are retracted out of the processing chamber 10 and the next wafer W is carried into the processing chamber 10 by the loading arms. By repeating the above-described operations, the wafers W are continuously processed.

[Conventional Stage]

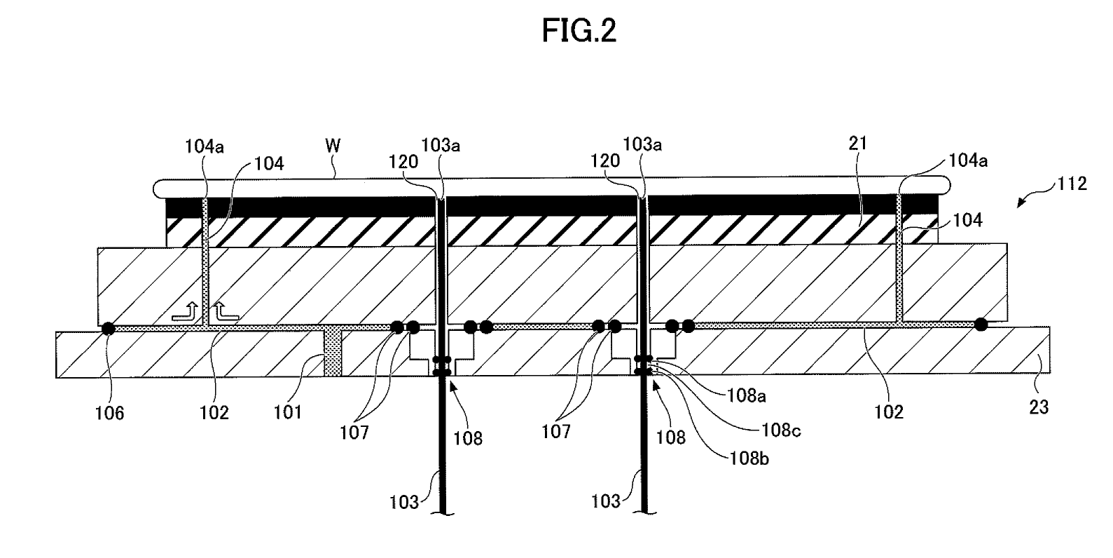

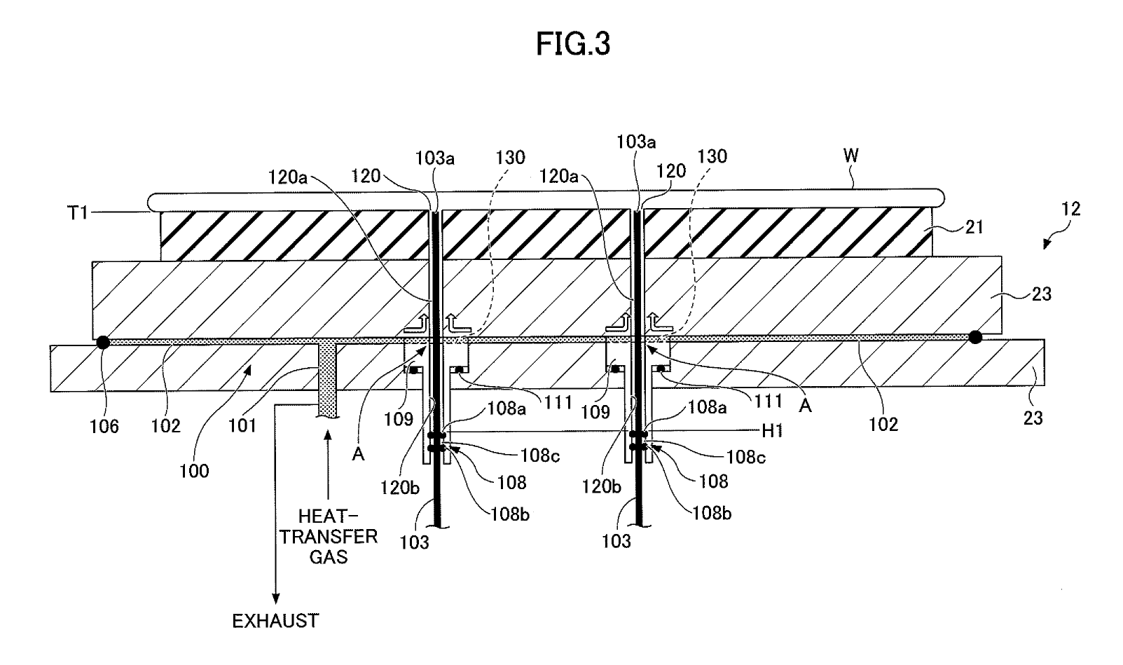

Next, after describing an example of a conventional stage 112 by referring to FIG. 2, a stage 12 that includes a raising-and-lowering mechanism according to an embodiment of the present invention will be described in detail by referring to FIG. 3. FIG. 2 is a drawing illustrating an example of a conventional stage 112. With the conventional stage 112, a heat-transfer gas output from the heat-transfer gas supplying source 105 is introduced to a heat-transfer gas supplying path 102 through a heat-transfer gas supplying pipe 101. The heat-transfer gas supplying path 102 extends in the base 23 of the stage 112 in a horizontal direction. Further, the heat-transfer gas goes through a heat-transfer gas supplying path 104 that communicates with the heat-transfer gas supplying path 102 and extends in the stage 112 in a vertical direction, and the heat-transfer gas is introduced onto the upper surface of the electro-static chuck 21 from the heat-transfer gas supplying holes 104a.

In the conventional stage 112, O-shaped rings 106 and 107 are provided in the heat-transfer gas supplying path 102. The O-shaped rings 107 separates the pin insertion holes 120, in which the lifter pins 103 are inserted, from the heat-transfer gas supplying path 102 to prevent the heat-transfer gas from going into the pin insertion holes 120. The O-rings 106 prevents the heat-transfer gas from leaking out into a processing space in the processing chamber 10.

Lubrication units 108 are provided around the lifter pins 103 in the pin insertion holes 120. In the lubrication units 108, a lubricant such as a grease is contained in lubrication spaces 108c that are gap spaces between ring-shaped members 108a and 108b. The lubricant is applied little by little onto the surfaces of the lifter pins 103 from the lubrication spaces 108c to allow smooth movement of the lifter pins 103 according to the up-and-down movement of the lifter pins 103. With the above arrangement, it is possible to raise and lower the lifter pins 103 smoothly.

It should be noted that a vacuum processing space is partitioned from an atmospheric space by the O-rings 106 and 107 and the ring-shaped members 108a and 108b.

[Stage According to an Embodiment of the Present Invention]

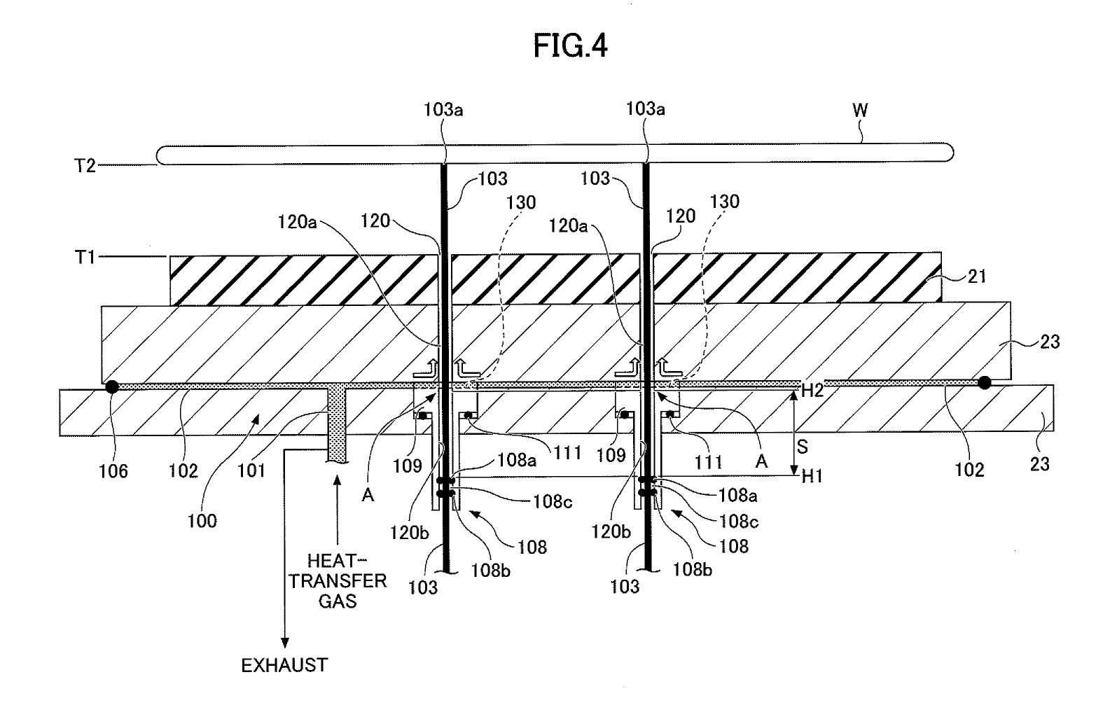

Next, a stage 12 and a raising-and-lowering mechanism of a wafer W according to an embodiment of the present invention will be described by referring to FIG. 3 and FIG. 4. FIG. 3 and FIG. 4 are drawings illustrating examples of a stage 12 including a raising-and-lowering mechanism of a wafer W according to an embodiment of the present invention. FIG. 3 illustrates an example of a stage 12 in a state in which the lifter pins 103 are lowered. FIG. 4 illustrates an example of a stage 12 in a state in which the lifter pins 103 are raised.

A raising-and-lowering mechanism of a wafer W included in a stage 12 according to an embodiment of the present invention includes a pin insertion hole 120, a lifter pin 103, a drive unit 36, and a lubrication unit 108 that is disposed at a predetermined height between the pin insertion hole 120 and the lifter pin 103 and is used for supplying a lubricant to the lifter pin 103.

Further, the raising-and-lowering mechanism includes a heat-transfer gas supplying unit 100. The heat-transfer gas supplying unit 100 includes a heat-transfer gas supplying path 102 that communicates with the pin insertion hole 120 at a position higher than the lubrication unit 108 and that supplies a heat-transfer gas to the pin insertion hole 120.

The pin insertion hole 120 is disposed in the stage 12 and penetrates through the stage 12 in an up-and-down direction. The lifter pin 103 is inserted through the pin insertion hole 120 and is raised and lowered in the up-and-down direction. The lubrication unit 108 is disposed around the lifter pin 103 at a position lower than the heat-transfer gas supplying path 102 that communicates with the pin insertion hole 120. In the lubrication unit 108, a lubricant such as a grease is contained in a lubrication space 108c that is a gap space between the ring-shaped members 108a and 108b.

The O-ring 106 functions to prevent the heat-transfer gas from leaking out into the processing space side. Further, a vacuum processing space is partitioned from an atmospheric space by the ring-shaped members 108a and 108b and an O-ring 111.

With the above-described arrangement, a heat-transfer gas output from the heat-transfer gas supplying source 105 is caused to go through the heat-transfer gas supplying path 102 to the pin insertion hole 120 via the heat-transfer gas supplying pipe 101, and is supplied to an upper surface of the electro-static chuck 21 from the opening of the pin insertion hole 120. With the above-described arrangement, it is possible to supply a heat-transfer gas to between the upper surface of the electro-static chuck 21 and the lower surface of the wafer W.

A groove 130 is formed at a portion of the heat-transfer gas supplying path 102 at which the heat-transfer gas supplying path 102 communicates with the pin insertion hole 120. The groove 130 is formed on an upper surface of a member 109 that includes a through hole that forms a part of the pin insertion hole 120. A single groove 130 may be formed on the upper surface of the member 109. A plurality of grooves 130 may be formed on the upper surface of the member 109. With the above-described arrangement, a heat-transfer gas is caused to flow smoothly at a point A at which the heat-transfer gas supplying path 102 crosses the pin insertion hole 120, and is caused to flow into the side of the wafer W without staying at the point A.

As described above, when compared with the conventional stage 112 illustrated in FIG. 2, in the stage 12 according to an embodiment of the present invention, an O-ring 107 is not provided in the heat-transfer gas supplying path 102 that extends in the stage 12 in the horizontal direction. Further, in the stage 12 according to an embodiment of the present invention, the heat-transfer gas supplying path 104, which extends in the vertical direction within the conventional stage 112 illustrated in FIG. 2, is not provided.

With the above-described arrangement, it is possible to omit the heat-transfer gas supplying path 104 illustrated in FIG. 2 by using the pin insertion hole 120 not only as a hole for raising and lowering the lifter pin 103 but also as a path for a heat-transfer gas. As a result, the heat-transfer gas supplying hole 104a illustrated in FIG. 2 is not formed on the upper surface of the stage 12 according to an embodiment of the present invention, and thus, it is possible to prevent occurrence of an abnormal discharge between the upper surface of the stage 12 and the lower surface of the wafer W.

[Position of Lubrication Unit According to an Embodiment of the Present Invention]

According to an embodiment of the present invention, a heat-transfer gas is supplied to the upper surface of the stage 12 from the pin insertion hole 120 that penetrates through the stage 12. Therefore, it is concerned that the inside of the processing chamber 10 may be contaminated because a lubricant as a particle is introduced to the plasma side of the wafer W together with the heat-transfer gas from the pin insertion hole 120 of the lifter pin 103.

Therefore, in order to prevent the lubricant from being introduced to the plasma side (wafer W side) together with the heat-transfer gas, the lubrication unit 108 is disposed at a position lower than the heat-transfer gas supplying path 102 of the heat-transfer gas supplying unit 100. Furthermore, the lubricant is supplied to the lifter pin 103 at a position H1 of the lubrication unit 108 when the lifter pin 103 is at a lowest position illustrated in FIG. 3. It is possible for the lubricant to move to a position H2 illustrated in FIG. 4 as the lifter pin 103 is raised to a highest position illustrated in FIG. 4.

In a state in which the wafer W is placed on the stage, the lifter pin 103 is at a lowest position at which the lifter pin 103 is lowered most. In other words, when the lifter pin 103 is at the lowest position illustrated in FIG. 3, the tips 103a of the lifter pins 103 are lowered to a height T1 that is the height of the upper surface of the electro-static chuck 21 (stage 12), and the wafer W is in a state in which the wafer W is placed on the electro-static chuck 21.

The highest position of the lifter pins 103 is a position at which the lifter pins 103 are raised most while holding the wafer W thereon. In other words, when the lifter pins 103 are at the highest position illustrated in FIG. 4, the tips 103a of the lifter pins 103 protrude from the upper surface of the electro-static chuck 21, and the wafer W is in a state in which the wafer W is raised most to a position T2.

A distance between the lowest position and the highest position of the lifter pins 103 is the maximum raising-and-lowering amount of the lifter pins 103 illustrated as a stroke S in FIG. 4. As described above, by taking into account the raising-and-lowering amount of the lifter pins 103 when the lifter pins 103 are raised and lowered between the lowest position and the highest position, the heat-transfer gas supplying path 102 communicates with the pin insertion holes 120 at a position that is separated upwards from the lubrication unit 108 by an amount greater than the raising-and-lowering amount of the lifter pins 103.

In other words, the lubrication unit 108 is disposed at a position separated from the heat-transfer gas supplying path 102 in such a way that a distance from a position A at which the heat-transfer gas supplying path 102 communicates with the pin insertion holes 120 to the lubrication unit 108 is greater than the maximum raising-and-lowering amount of the lifter pins 103 (stroke S in FIG. 4).

Because the heat-transfer gas is supplied to between the upper surface of the stage 12 and the lower surface of the wafer W during a period when the wafer W is placed on the stage 12, a portion 120b of the pin insertion hole 120 in the member 109 is filled with the heat-transfer gas during the period. Therefore, the heat-transfer gas, which is in contact with the lubricant attached to the lifter pins 103, does not go through a portion 120a, of the heat-transfer gas supplying path 102 and the pin insertion holes 120, that is positioned higher than the heat-transfer gas supplying path 102 to be introduced to the plasma side of the processing chamber 10.

When the wafer W is not placed on the stage 12, the heat-transfer gas, with which the portion 120b of the pin insertion hole 120 of the member 109 is filled and with which the lubricant is in contact, is caused to go through the heat-transfer gas supplying path 102 and is exhausted through the heat-transfer gas supplying pipes 101 according to the exhaust apparatus that is connected to the heat-transfer gas supplying pipes 101. Therefore, the heat-transfer gas that is in contact with the lubricant is not caused to go through the pin insertion holes 12 to be introduced to the plasma side of the processing chamber 10 not only while the wafer W is placed on the stage 12 but also while the wafer W is not placed on the stage 12.

As described above, in the stage 12 including a raising-and-lowering mechanism according to an embodiment of the present invention, the pin insertion holes 120 are commonly used for raising and lowering the lifter pins 103 and for a path for the heat-transfer gas. With the above arrangement, it is possible to omit heat-transfer gas supplying holes dedicated to supplying the heat-transfer gas and it is possible to prevent occurrence of an abnormal discharge between the upper surface of the stage 12 and the lower surface of the wafer W.

In addition to the above arrangement, the lubrication unit 108 is disposed at a position lower than the heat-transfer gas supplying path 102. More preferably, the lubrication unit 108 is disposed by separating from the heat-transfer gas supplying path 102 by a raising-and-lowering amount of the lifter pins 103. With the above arrangement, even when the tips 103a of the lifter pins 103 are raised from a position T1 of an upper surface of the electro-static chuck 21 by an amount of the stroke to reach the highest position T2, portions of the lifter pins 103, to which the lubricant is applied, still do not reach the heat-transfer gas supplying path 102. With the above arrangement, it is possible to prevent the lubricant, which is applied to the surface of the lifter pins 103, from contacting the heat-transfer gas.

It should be noted that, because the maximum raising-and-lowering amount of the lifter pins 103 differs according to the plasma processing apparatuses 1, it is preferable that the lubrication unit 108 is disposed at a position lower than the maximum raising-and-lowering amount (maximum stroke) of the lifter pins 103 of each of the plasma processing apparatuses 1.

### Modified Example

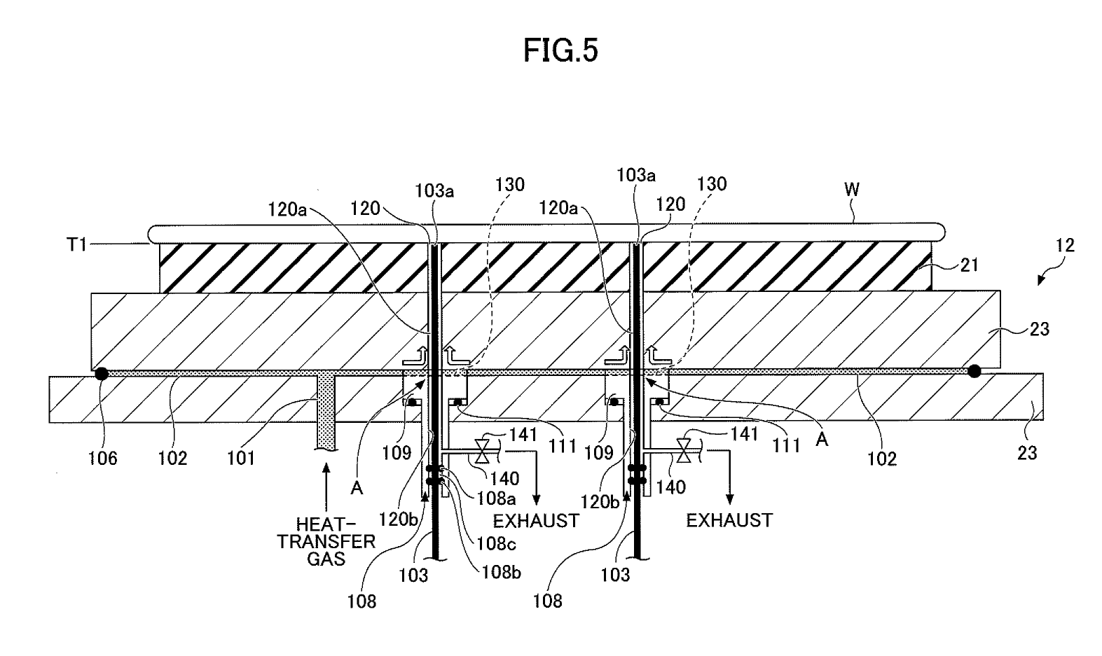

At the end of the description, referring to FIG. 5, a stage 12 according to a modified embodiment of the present invention will be described. FIG. 5 is a drawing illustrating a modified example of a stage 12 according to an embodiment of the present invention. The stage 12 according to a modified embodiment of the present invention is different from the stage 12 according to an embodiment of the present invention in that: an exhaust pipe 140 connected to an exhaust apparatus communicates with the portion 120b of the pin insertion hole 120 of the member 109; and a heat-transfer gas in the pin insertion hole 120 and a heat-transfer gas in the heat-transfer gas supplying path 102 are exhausted from the portion 120b of the pin insertion hole 120. Other parts of the stage 12 according to a modified embodiment are the same as the stage 12 according to an embodiment. Therefore, the above-described part alone will be described.

The exhaust pipe 140 is connected to the member 109. The exhaust pipe 140 communicates with the portion 120b of the pin insertion hole 120 in the member 109. The exhaust pipe 140 is disposed between: a portion A of the heat-transfer gas supplying path 102 at which the heat-transfer gas supplying path 102 communicates with the pin insertion hole 120; and the lubrication unit 108. In other words, the exhaust pipe 140 communicates with the pin insertion hole 120 at a position, indicated by the stroke S in FIG. 4, of the portion 120b of the pin insertion hole 120.

An orifice 141 is provided in the exhaust pipe 140. It is possible to provide a narrowing part in the exhaust pipe 140 by the orifice 141, and it is possible to exhaust a minute flow amount of the heat-transfer gas as a normal operation. With the above arrangement, it is possible to exhaust the heat-transfer gas that has touched the lubricant through the opened exhaust pipe 140. With the above arrangement, it is possible to prevent the heat-transfer gas that has touched the lubricant from flowing into the portion 120a, of the pin insertion hole 120, that is positioned higher than the heat-transfer gas supplying path 102, and from being introduced to the plasma side.

Further, in the modified embodiment, the heat-transfer gas that touches the lubricant is exhausted without going through the heat-transfer gas supplying path 102. With the above arrangement, it is possible to supply the heat-transfer gas' to the lower surface of the wafer W from the pin insertion hole 120 without contaminating the processing chamber 10 with the lubricant. It should be noted that, according to the modified embodiment, by using the pin insertion hole 120 as a path for the heat-transfer gas, it is possible to omit heat-transfer gas supplying holes dedicated to supplying the heat-transfer gas and it is possible to prevent occurrence of an abnormal discharge between the upper surface of the stage 12 and the lower surface of the wafer W.

As described above, according to a stage 12 including a raising-and-lowering mechanism and a plasma processing apparatus 1 according to an embodiment and a modified embodiment of the present invention, the heat-transfer gas is supplied to the lower surface of the wafer W from the pin insertion hole 120. With the above arrangement, because of the insulative member 109, compared with the case in which the heat-transfer gas is supplied from the heat-transfer gas supplying pipe 101, an abnormal discharge does not readily occur at the pin insertion hole 120, and it becomes possible to prevent an abnormal discharge at the stage 12.

As described above, a raising-and-lowering mechanism, a stage, and a plasma processing apparatus according to an embodiment of the present invention have been described. The raising-and-lowering mechanism, the stage, and the plasma processing apparatus are not limited to the above-described embodiments, and various variations and modifications can be made within the scope of the present invention. Matters described in the embodiments may be combined within the non-conflicting range.

For example, the raising-and-lowering mechanism according to an embodiment and a modified embodiment of the present invention is included in the stage 12 with the electro-static chuck 21. However, for example, the raising-and-lowering mechanism may be included in the stage 12 without the electro-static chuck 21.

the plasma processing apparatuses according to an embodiment of the present invention may be applied to any type including Capacitively Coupled Plasma (CCP), Inductively Coupled Plasma (ICP), Radial Line Slot Antenna, Electron Cyclotron Resonance Plasma (ECR), and Helicon Wave Plasma (HWP).

In the present specification, a semiconductor wafer W is described as an example of an object to be processed. However, the object to be processed is not limited to the semiconductor wafer W, and may be various types of substrates used for LCD (Liquid Crystal Display) and FPD (Flat Panel Display), CD substrates, printed boards, etc.

The present application is based on and claims priority to Japanese patent application No. 2018-018005 filed on Feb. 5, 2018, the entire contents of which are hereby incorporated herein by reference.

### DESCRIPTION OF THE REFERENCE NUMERALS

1 plasma processing apparatus
10 processing chamber
12 stage
21 electro-static chuck
23 base
25 focus ring
30 gas supplying source
32 first high-frequency power source
34 second high-frequency power source
40 gas shower head
100 heat-transfer gas supplying unit
102 heat-transfer gas supplying path
103 lifter pin
103a tip
105 heat-transfer gas supplying source
106, 107 O-ring
108 lubrication unit
108c lubrication space
109 member
113 DC power supply
120 pin insertion hole
140 exhaust pipe
141 orifice
200 control unit

What is claimed is:

1. A raising-and-lowering mechanism for a processing target, the raising-and-lowering mechanism comprising:
a pin insertion hole that is disposed in a stage, on which the processing target that is to be processed in a processing chamber is placed, the pin insertion hole penetrating through the stage in an up-and-down direction;
a lifter pin that is inserted through the pin insertion hole and is raised and lowered in the up-and-down direction;
a lubrication unit that is disposed at a predetermined height between the pin insertion hole and the lifter pin, and that supplies a lubricant to the lifter pin;
a drive unit that drives the lifter pin in the up-and-down direction; and
a heat-transfer gas supplying unit that
includes a heat-transfer gas supplying path communicating with the pin insertion hole at a position higher than the lubrication unit, and
supplies a heat-transfer gas to the pin insertion hole.

2. The raising-and-lowering mechanism according to claim 1, wherein the heat-transfer gas supplying unit causes the heat-transfer gas to flow to the pin insertion hole via the heat-transfer gas supplying path and to be supplied onto an upper surface of the stage.

3. The raising-and-lowering mechanism according to claim 1, wherein the heat-transfer gas supplying path communicates with the pin insertion hole at a position that is higher than the lubrication unit and is separated from the lubrication unit by a distance longer than a raising-and-lowering amount of the lifter pin.

4. The raising-and-lowering mechanism according to claim 3, wherein the raising-and-lowering amount of the lifter pin is a movement amount of the lifter pin from a lowest position when the processing target is placed on the stage to a highest position when the processing target is lifted most by the lifter pin.

5. The raising-and-lowering mechanism according to claim 1, wherein a groove is formed at a portion of the heat-transfer gas supplying path at which the heat-transfer gas supplying path communicates with the pin insertion hole.

6. The raising-and-lowering mechanism according to claim 1, further comprising:
an exhaust pipe that is inserted in the pin insertion hole and is used for exhausting a heat-transfer gas.

7. The raising-and-lowering mechanism according to claim 6, wherein the exhaust pipe is disposed between
the portion of the heat-transfer gas supplying path at which the heat-transfer gas supplying path communicates with the pin insertion hole, and
the lubrication unit.

8. The raising-and-lowering mechanism according to claim 1, further comprising:
an exhaust pipe that is inserted in the pin insertion hole and is used for exhausting a heat-transfer gas,
wherein the exhaust pipe is disposed between
the portion of the heat-transfer gas supplying path at which the heat-transfer gas supplying path communicates with the pin insertion hole, and
the lubrication unit,
wherein the heat-transfer gas supplying unit causes the heat-transfer gas to flow to the pin insertion hole via the heat-transfer gas supplying path and to be supplied onto an upper surface of the stage,
wherein the heat-transfer gas supplying path communicates with the pin insertion hole at a position that is higher than the lubrication unit and is separated from the lubrication unit by a distance longer than a raising-and-lowering amount of the lifter pin,
wherein the raising-and-lowering amount of the lifter pin is a movement amount of the lifter pin from a lowest position when the processing target is placed on the stage to a highest position when the processing target is lifted most by the lifter pin, and
wherein a groove is formed at a portion of the heat-transfer gas supplying path at which the heat-transfer gas supplying path communicates with the pin insertion hole.

9. A stage that includes a raising-and-lowering mechanism, the stage comprising:
a pin insertion hole disposed in a stage, on which a processing target that is to be processed in a processing chamber is placed, the pin insertion hole penetrating through the stage in an up-and-down direction;
a lifter pin that is inserted through the pin insertion hole and is raised and lowered in the up-and-down direction;
a lubrication unit that is disposed at a predetermined height between the pin insertion hole and the lifter pin, and that supplies a lubricant to the lifter pin;
a drive unit that drives the lifter pin in the up-and-down direction; and
a heat-transfer gas supplying unit that
includes a heat-transfer gas supplying path communicating with the pin insertion hole at a position higher than the lubrication unit, and
supplies a heat-transfer gas to the pin insertion hole.

10. A plasma processing apparatus comprising: a stage, on which a processing target that is to be processed in a processing chamber is placed; and a raising-and-lowering mechanism by which the processing target is raised and lowered, wherein the raising-and-lowering mechanism includes
a pin insertion hole that is disposed in the stage and penetrates through the stage in an up-and-down direction,
a lifter pin that is inserted through the pin insertion hole and is raised and lowered in the up-and-down direction,
a lubrication unit that is disposed at a predetermined height between the pin insertion hole and the lifter pin, and that supplies a lubricant to the lifter pin,
a drive unit that drives the lifter pin in the up-and-down direction, and
a heat-transfer gas supplying unit that
includes a heat-transfer gas supplying path communicating with the pin insertion hole at a position higher than the lubrication unit and
supplies a heat-transfer gas to the pin insertion hole.
